(19) United States
(12) Patent Application Publication
(10) Pub. No.: US 2022/0075907 A1
(43) Pub. Date: Mar. 10, 2022

(54) PLANOGRAM MANAGEMENT SYSTEM

(71) Applicant: SAP SE, Walldorf (DE)

(72) Inventors: Eduardo VELLASQUES, Berlin (DE); Kannan Presanna KUMAR, Berlin (DE); Jan Hendrik STOCKEMER, Berlin (DE); Urko Sanchez SANZ, Berlin (DE)

(21) Appl. No.: 17/015,833

(22) Filed: Sep. 9, 2020

(51) Int. Cl. G06F 30/10; G06K 9/00; G06K 9/62; G06Q 10/08; G06F 9/54

(52) U.S. Cl. CPC G06F 30/10; G06K 9/00664; G06F 9/542; G06Q 10/087; G06K 9/6202

(57) ABSTRACT

Disclosed herein are various embodiments for planogram management system. An embodiment operates by receiving a planogram of a retail establishment. The planogram indicates a relative location of a plurality of items offered for sale by the retail establishment placed across one or more retail locations within the retail establishment. An image of a first one of the retail locations of the retail establishment is received. The image is compared to the portion of the planogram corresponding to the first one of the retail locations, and one or more differences between the image and the portion of the planogram for the first retail location are identified. An employee of the retail establishment is notified of the one or more differences.

### BACKGROUND

Planograms are layouts or diagrams of stores or other retail establishments that indicate which products are being offered for sale, and where those products are located. Creating a planogram is often a time, labor, and resource intensive process that often requires an employee or other personnel walking around the store and manually identifying and noting the locations of the various products in a retail establishment. Further, the planogram is only useful to the extent that the products in the store are actually located where they are supposed to be as indicated by the planogram.

### BRIEF DESCRIPTION OF THE DRAWINGS

The accompanying drawings are incorporated herein and form a part of the specification.

FIG. 1 is a block diagram illustrating example functionality related to operations of example planogram management system (PMS), according to some example embodiments.

FIG. 2 is a flowchart illustrating example operations for providing a planogram management system (PMS), according to some embodiments.

FIG. 3 is an example computer system useful for implementing various embodiments.

In the drawings, like reference numbers generally indicate identical or similar elements. Additionally, generally, the left-most digit(s) of a reference number identifies the drawing in which the reference number first appears.

### DETAILED DESCRIPTION

Planograms are layouts or diagrams of stores or other retail establishments that indicate which products are being offered for sale, and where those products are located. Creating a planogram is often a time, labor, and resource intensive process that often requires an employee or other personnel walking around the store and manually identifying and noting the locations of the various products in a retail establishment. Further, the planogram is only useful to the extent that the products in the store are actually located where they are supposed to be as indicated by the planogram.

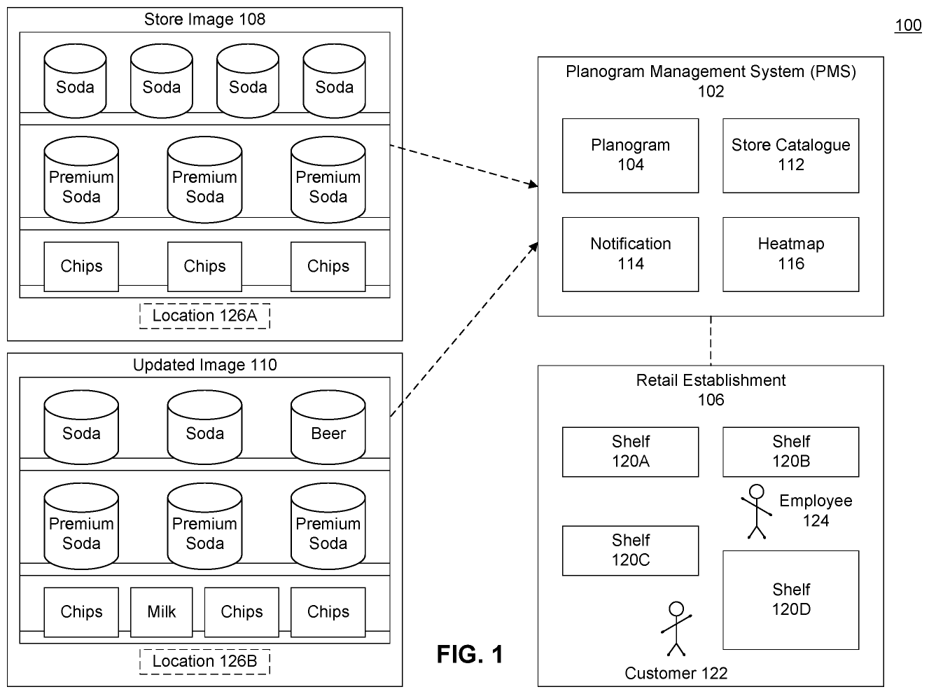

FIG. 1 is a block diagram 100 illustrating example functionality related to operations of example planogram management system (PMS) 102, according to some example embodiments. Rather than requiring the manual creation of a planogram by having various employees walk around a store and make manual notations as to what products are located in what areas of a store, PMS 102 enables for image-based planogram 104 creation and management.

A planogram 104 may be a layout or diagram of a retail establishment 106 that indicates which products are being offered for sale, and where those products are located within the retail establishment 106. The planogram 104 may indicate what shelf 120A-D of the retail establishment 106 includes which products. Each shelf 120A-D may be a display case that includes one or more shelves, hangers, or other organizational fixtures for displaying products for sale within retail establishment 106. Each shelf 120A-D may include a single product, a category of products, or a variety of different products and/or categories.

Retail establishment 106 may include any store, booth, sales vehicle, yard, open area, or other location where products and/or services are being displayed and offered for sale to a customer 122. Example retail establishments 106 include a self-contained enclosed brick and mortar store, an outdoor flea market or farmers' market with different booths from different vendors, or items arranged in someone's yard for a yard sale. Employee 124 may be any person who is employed by or otherwise associated with retail establishment 106, either directly or indirectly who may help organize or sell products. Customer 122 may be any person who is in retail establishment 106 to browse, purchase and/or pickup products or services.

In an embodiment, PMS 102 may generate planogram 104 for retail establishment 106 based on one or more received store images 108. Store images 108 may include pictures, video, or other multimedia taken of retail establishment 106 that show an organization and/or locations of the various products offered for sale within retail establishment 106, or a portion thereof. In an embodiment, store images 108 may indicate a relative placement of those products to one another, and an objective or absolute placement of those products within a blueprint or layout of retail establishment 106. For example, store image 108 shows how a variety of different products (soda, premium soda, and chips) are arranged relative to each other (premium products on top shelf, company X products on the left side, product Y on middle shelf, product Z on hanger, etc.), but may also include an indication as to which shelf 120A-D those products are located (e.g., northeast corner, front near the door, etc.).

In an embodiment, the location within retail establishment 106 of the received store images 108 may be based on an indoor locational positioning system or outdoor GPS (global position system) or other locational tracking technology. For example, employee 124 may walk around retail establishment taking or streaming pictures or video of the various products on shelves 120A-D and a locational tracking system may align the incoming data with particular locations or shelves 120A-D within retail establishment 106. In another embodiment, store image 108 may include a QR (quick response) code or shelf identifier, identifying to which shelf 120A-D each store image 108 corresponds.

In an embodiment, PMS 102 may receive or have access to a store catalogue 112. Store catalogue 112 may be an electronic manual, database, or other data collection that includes identifications of various products offered for sale within retail establishment 106 and corresponding images of those products.

In an embodiment, PMS 102 may include a machine learning model or system that is configured to learn how to identify the products of store catalogue 112 from various images. Some example machine learning systems may include neural network or deep learning systems, as well statistical or event-tree based models. PMS 102 may compare the received store image(s) 108 to store catalogue 112, and may identify the various products in the image 108 without employee 124 or other user input. In an embodiment, PMS 102 may use OCR (optical character recognition) or other image or object recognition techniques for the identification process.

In an embodiment, PMS 102 may combine the identification of the products in the received store images 108 (through comparisons with store catalogue 112) with the location 126A for each store image 108 to construct a planogram 104 for retail establishment 106. As noted above, store image 108 may be a video or still image of a portion of retail establishment 106. Though only one store image 108 is shown in the example, it is understood that numerous store images 108 may be used to construct planogram 104.

Using the location 126 and identification information, PMS 102 may generate a planogram 104 that indicates what products are located in which shelves 120A-D, and the relative arrangements of those products to one another on each particular shelf 120A-D. Planogram 104 may also include a relative location of the shelves 120A-D to one another, or may include a physical blueprint or layout of each shelf 120A-D in retail establishment 106. In an embodiment, planogram 104 may include other information such as product cost, sales price, inventory information, sales promotions, related products, etc. In an embodiment, this other information may be received in part from store catalogue 112 or from point-of-sales (POS) systems.

In an embodiment, PMS 102 may generate an initial planogram 104 indicating a starting arrangement of products across shelves 120A-D of retail establishment 106. However, through customer 122 and/or employee 124 interactions, the original assortment of products may not remain as they were originally arranged. For example, a customer 122 may pick up a product from shelf 120D, walk around retail establishment 106, and leave the product at shelf 120A after changing their mind. Or, for example, employee 124 may place a returned product or new inventory in the wrong or a different location than originally located (as indicated by planogram 104).

In an embodiment, employees 124 may submit updated images 110 to PMS 102 that indicate a current arrangement of products across one or more shelves 120A-D. As described above with respect to store image 108, updated image 110 may include its own location 126B information. Similar to location 126A, the location 126B may indicate to which particular shelf or shelves 120A-D updated image 110 pertains.

In an embodiment, updated image 110 may not include location 126B information.

In such embodiments, PMS 102 may identify a location 126B of the updated image 110 based on identifying the various products shown in the updated image 110 based on store catalogue 112 and identifying the location of those products based on planogram 104.

If an updated image 110 includes multiple products, some of which are out of place, and no location 126B, PMS 102 may compare those parts of planogram with the most overlapping correspondence between identified products in with the most products that correspond to the identified products from updated image 110. For example, if an updated image 110 includes 4 different toys, three dolls and a soccer ball, PMS 102 may determine, based on planogram 104, that location 126B corresponds to the shelf 120A-D of retail establishment 106 with the dolls, and not the soccer balls and that the soccer ball is out of place.

PMS 102 may receive updated image 110 and identify which product(s) if any need to be rearranged by one or more employees 124 in accordance with planogram 104. For example, as noted above, products may be moved or misplaced during normal operations by customers 122 and/or employees 124. Or, for example, planogram 104 may be updated based on a new sales strategy in which various products may be moved around the store or retail establishment 106. For example, a planogram 104 update may include an indication that shoes may be moved from shelf 120D to shelf 120A near socks, and the store may stop carrying or replace a particular brand of razors which may be located on shelf 120B.

In an embodiment, PMS 102 may receive one or more updated images 110 and compare those images against the most recent or updated planogram 104 to identify which products in updated image 110 need to be moved, rearranged, are out of place, or need to be restocked. For example, if planogram 104 for shelf 120C was generated based on store image 108 and an employee 124 sends updated image 110 of shelf 120C, PMS 102 may identify which product(s) need to be rearranged or moved, and where, from updated image 110.

For example, based on a comparison of updated image 110 to store image 108, PMS 102 may generate a notification 114 to employee 124 that indicates both Beer and Milk are out of place, and may indicate the relative locations in the retail establishment 106 where those products need to be moved. PMS 102 may also determine that there needs to be at least four soda packs on the shelf, and may generate a notification 114 to employee to restock the shelf with at two more sodas. In an embodiment, PMS 102 may be able to use image processing to identify empty spaces on shelves where products can or should be placed or restocked.

In an embodiment, planogram 104 may have been updated to reflect a new sales strategy in which premium or the most expensive products are located on the top shelf. As such, upon receiving updated image 110, PMS 102 may indicate to employee 124 to move the premium soda to the top shelf and the soda to the middle shelf. In another embodiment, this notification 114 of product movement based on updated sales strategies applied to planogram 104 and may be communicated to employees 124 without first receiving an updated image 110. For example, based on planogram 104 PMS 102 may already know that shelf 120C is out of alignment with the top-shelf premium product sales strategy and may signal an employee 124, on their mobile device, to make the change to the arrangement of products.

In an embodiment, retail establishment 106 may include various video cameras, motion sensor cameras, or snapshot cameras arranged across one or more locations or in front of one or more shelves 120A-D around retail establishment. In an embodiment, PMS 102 may receive updated images 110 from these cameras. In an embodiment, these camera images may indicate customer interactions with various shelves 120A-D. Based on the updated images 110 (which may include video), updates to sales strategies and planogram 104 may be updated. For example, if a customer 122 appears confused in front of a shelf 120D, then the arrangement of the products of shelf 120D may be updated in planogram 104. The update may then be transmitted via notification 114 to employee 124 to implement.

In an embodiment, PMS 102 may receive or generate a heatmap 116. Heatmap 116 may indicate a path traveled by one or more customers 122 into store, and where the customer 122 spent time (e.g. in front of which shelves 120A-D or aisles). In an embodiment, PMS 102 may receive or generate heatmap 116 based on the various cameras or by tracking customer positions based on network signals or GPS or indoor positioning system. Based on heatmap 116, planogram 104 may be updated to place various products in likely paths through retail establishment 106 that an average customer 122 travels. For example, if 90% of customers use aisle 3, then planogram 104 may be updated to place premium products on aisle 3.

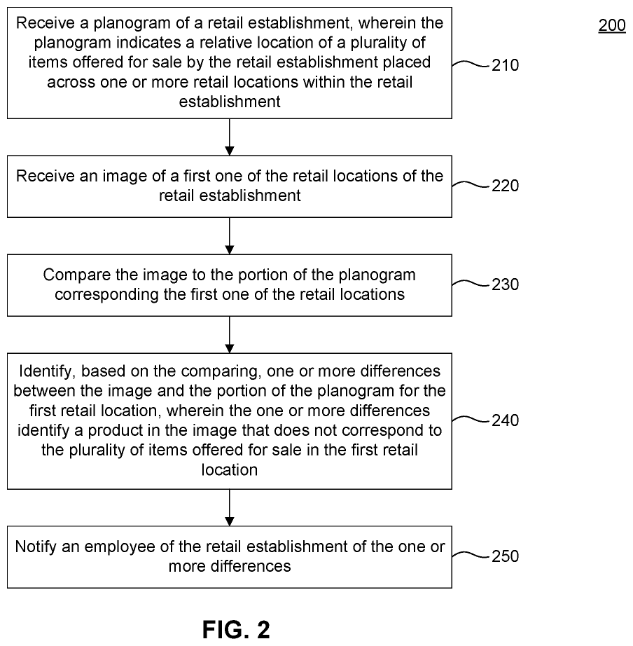

FIG. 2 is a flowchart 200 illustrating example operations for providing a planogram management system (PMS), according to some embodiments. Method 200 can be performed by processing logic that can comprise hardware (e.g., circuitry, dedicated logic, programmable logic, microcode, etc.), software (e.g., instructions executing on a processing device), or a combination thereof. It is to be appreciated that not all steps may be needed to perform the disclosure provided herein. Further, some of the steps may be performed simultaneously, or in a different order than shown in FIG. 2, as will be understood by a person of ordinary skill in the art. Method 200 shall be described with reference to the figures.

In 210, a planogram of a retail establishment is received, wherein the planogram indicates a relative location of a plurality of items offered for sale by the retail establishment placed across one or more retail locations within the retail establishment. For example, PMS 102 may generate a planogram 104 of retail establishment 106 based on a series of store images 108 (which may include still images and/or video) received of the various products arranged across the shelves 120A-D.

In 220, an image of a first one of the retail locations of the retail establishment is received. For example, PMS 102 may receive updated image 110 which may include a location 126B that corresponds to a shelf 120A-D of retail establishment 106.

In 230, the image is compared to the portion of the planogram corresponding to the first one of the retail locations. For example, PMS 102 may identify a portion of planogram 104 (which may include one or more images, or another indication of which products are expected and their respective orders) corresponding to location 126B.

In 240, one or more differences between the image and the portion of the planogram for the first retail location are identified based on the comparing, wherein the one or more differences identify a product in the image that does not correspond to the plurality of items offered for sale in the first retail location. For example, PMS 102 may compare updated image 110 to the identified portion of planogram 104 to identify which products are out of place, need to be moved, or need to be restocked.

In 250, an employee of the retail establishment is notified of the one or more differences. For example, PMS 102 may transmit a notification 114 to employee 124 indicating that the beer and milk need to be moved, the premium soda belongs on the top shelf, and the soda needs to be restocked.

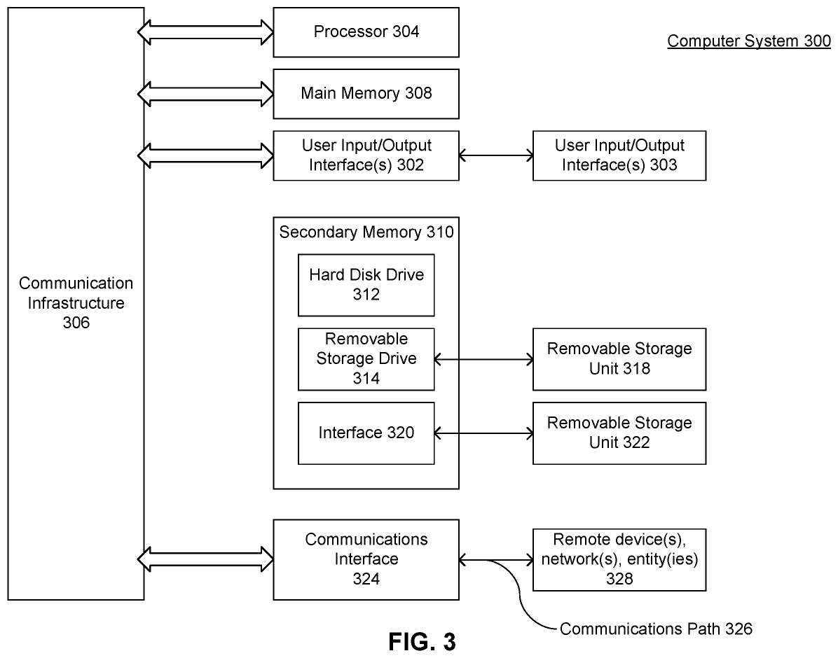

Various embodiments may be implemented, for example, using one or more well-known computer systems, such as computer system 300 shown in FIG. 3. One or more computer systems 300 may be used, for example, to implement any of the embodiments discussed herein, as well as combinations and sub-combinations thereof.

Computer system 300 may include one or more processors (also called central processing units, or CPUs), such as a processor 304. Processor 304 may be connected to a communication infrastructure or bus 306.

Computer system 300 may also include customer input/output device(s) 303, such as monitors, keyboards, pointing devices, etc., which may communicate with communication infrastructure 306 through customer input/output interface(s) 302.

One or more of processors 304 may be a graphics processing unit (GPU). In an embodiment, a GPU may be a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 300 may also include a main or primary memory 308, such as random-access memory (RAM). Main memory 308 may include one or more levels of cache. Main memory 308 may have stored therein control logic (i.e., computer software) and/or data.

Computer system 300 may also include one or more secondary storage devices or memory 310. Secondary memory 310 may include, for example, a hard disk drive 312 and/or a removable storage device or drive 314. Removable storage drive 314 may be a floppy disk drive, a magnetic tape drive, a compact disk drive, an optical storage device, tape backup device, and/or any other storage device/drive.

Removable storage drive 314 may interact with a removable storage unit 318.

Removable storage unit 318 may include a computer usable or readable storage device having stored thereon computer software (control logic) and/or data. Removable storage unit 318 may be a floppy disk, magnetic tape, compact disk, DVD, optical storage disk, and/any other computer data storage device. Removable storage drive 314 may read from and/or write to removable storage unit 318.

Secondary memory 310 may include other means, devices, components, instrumentalities or other approaches for allowing computer programs and/or other instructions and/or data to be accessed by computer system 300. Such means, devices, components, instrumentalities or other approaches may include, for example, a removable storage unit 322 and an interface 320. Examples of the removable storage unit 322 and the interface 320 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computer system 300 may further include a communication or network interface 324.

Communication interface 324 may enable computer system 300 to communicate and interact with any combination of external devices, external networks, external entities, etc. (individually and collectively referenced by reference number 328). For example, communication interface 324 may allow computer system 300 to communicate with external or remote devices 328 over communications path 326, which may be wired and/or wireless (or a combination thereof), and which may include any combination of LANs, WANs, the Internet, etc. Control logic and/or data may be transmitted to and from computer system 300 via communication path 326.

Computer system 300 may also be any of a personal digital assistant (PDA), desktop workstation, laptop or notebook computer, netbook, tablet, smart phone, smart watch or other wearable, appliance, part of the Internet-of-Things, and/or embedded system, to name a few non-limiting examples, or any combination thereof.

Computer system 300 may be a client or server, accessing or hosting any applications and/or data through any delivery paradigm, including but not limited to remote or distributed cloud computing solutions; local or on-premises software (“on-premise” cloud-based solutions); “as a service” models (e.g., content as a service (CaaS), digital content as a service (DCaaS), software as a service (SaaS), managed software as a service (MSaaS), platform as a service (PaaS), desktop as a service (DaaS), framework as a service (FaaS), backend as a service (BaaS), mobile backend as a service (MBaaS), infrastructure as a service (IaaS), etc.); and/or a hybrid model including any combination of the foregoing examples or other services or delivery paradigms.

Any applicable data structures, file formats, and schemas in computer system 300 may be derived from standards including but not limited to JavaScript Object Notation (JSON), Extensible Markup Language (XML), Yet Another Markup Language (YAML), Extensible Hypertext Markup Language (XHTML), Wireless Markup Language (WML), MessagePack, XML User Interface Language (XUL), or any other functionally similar representations alone or in combination. Alternatively, proprietary data structures, formats or schemas may be used, either exclusively or in combination with known or open standards.

In some embodiments, a tangible, non-transitory apparatus or article of manufacture comprising a tangible, non-transitory computer useable or readable medium having control logic (software) stored thereon may also be referred to herein as a computer program product or program storage device. This includes, but is not limited to, computer system 300, main memory 308, secondary memory 310, and removable storage units 318 and 322, as well as tangible articles of manufacture embodying any combination of the foregoing. Such control logic, when executed by one or more data processing devices (such as computer system 300), may cause such data processing devices to operate as described herein.

Based on the teachings contained in this disclosure, it will be apparent to persons skilled in the relevant art(s) how to make and use embodiments of this disclosure using data processing devices, computer systems and/or computer architectures other than that shown in FIG. 3. In particular, embodiments can operate with software, hardware, and/or operating system implementations other than those described herein.

It is to be appreciated that the Detailed Description section, and not any other section, is intended to be used to interpret the claims. Other sections can set forth one or more but not all exemplary embodiments as contemplated by the inventor(s), and thus, are not intended to limit this disclosure or the appended claims in any way.

While this disclosure describes exemplary embodiments for exemplary fields and applications, it should be understood that the disclosure is not limited thereto. Other embodiments and modifications thereto are possible, and are within the scope and spirit of this disclosure. For example, and without limiting the generality of this paragraph, embodiments are not limited to the software, hardware, firmware, and/or entities illustrated in the figures and/or described herein. Further, embodiments (whether or not explicitly described herein) have significant utility to fields and applications beyond the examples described herein.

Embodiments have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative embodiments can perform functional blocks, steps, operations, methods, etc. using orderings different than those described herein.

References herein to “one embodiment,” “an embodiment,” “an example embodiment,” or similar phrases, indicate that the embodiment described can include a particular feature, structure, or characteristic, but every embodiment can not necessarily include the particular feature, structure, or characteristic. Moreover, such phrases are not necessarily referring to the same embodiment. Further, when a particular feature, structure, or characteristic is described in connection with an embodiment, it would be within the knowledge of persons skilled in the relevant art(s) to incorporate such feature, structure, or characteristic into other embodiments whether or not explicitly mentioned or described herein. Additionally, some embodiments can be described using the expression “coupled” and “connected” along with their derivatives. These terms are not necessarily intended as synonyms for each other. For example, some embodiments can be described using the terms “connected” and/or “coupled” to indicate that two or more elements are in direct physical or electrical contact with each other. The term “coupled,” however, can also mean that two or more elements are not in direct contact with each other, but yet still co-operate or interact with each other.

The breadth and scope of this disclosure should not be limited by any of the above-described exemplary embodiments, but should be defined only in accordance with the following claims and their equivalents.

What is claimed is:

1. A computer-implemented method comprising:
receiving a planogram of a retail establishment, wherein the planogram indicates a relative location of a plurality of items offered for sale by the retail establishment placed across one or more retail locations within the retail establishment;
receiving an image of a first retail location of the one or more retail locations;
comparing the image to a portion of the planogram corresponding to the first retail location;
identifying, based on the comparing, one or more differences between the image and the portion of the planogram for the first retail location, wherein the one or more differences identify a product in the image that does not correspond to the plurality of items offered for sale in the first retail location; and
notifying an employee of the retail establishment of the one or more differences.

2. The method of claim 1, wherein the identifying comprises:
identifying, based on the planogram, a second retail location of the one or more retail locations that includes the product.

3. The method of claim 2, wherein the notifying comprises:
notifying the employee of both the first retail location where the product is located, and the second retail location to which the product should be moved by the employee.

4. The method of claim 1, wherein the receiving the planogram comprises:
receiving a plurality of images corresponding to the one or more retail locations; and
generating the planogram based on the plurality of images, wherein the generating includes identifying and comparing objects within the plurality of images to a sales catalog include the plurality of items offered for sale by the retail establishment.

5. The method of claim 4, wherein the sales catalog includes, for at least a first item of the plurality of items offered for sale: an image of the first item, and a label identifying the first item.

6. The method of claim 1, wherein the receiving the image comprises:
receiving the image from the employee.

7. The method of claim 6, wherein the image comprises a video including the first retail location and one or more other of the one or more retail locations.

8. A system, comprising:
a memory; and
at least one processor coupled to the memory and configured to perform instructions that cause the at least one processor to perform operations comprising:
receiving a planogram of a retail establishment, wherein the planogram indicates a relative location of a plurality of items offered for sale by the retail establishment placed across one or more retail locations within the retail establishment;
receiving an image of a first retail location of the one or more retail locations;
comparing the image to the portion of the planogram corresponding to the first one of the retail locations;
identifying, based on the comparing, one or more differences between the image and the portion of the planogram for the first retail location, wherein the one or more differences identify a product in the image that does not correspond to the plurality of items offered for sale in the first retail location; and
notifying an employee of the retail establishment of the one or more differences.

9. The system of claim 8, wherein the identifying comprises:
identifying, based on the planogram, a second retail location of the one or more retail locations that includes the product.

10. The system of claim 9, wherein the notifying comprises:
notifying the employee of both the first retail location where the product is located, and the second retail location to which the product should be moved by the employee.

11. The system of claim 8, wherein the receiving the planogram comprises:
receiving a plurality of images corresponding to the one or more retail locations; and
generating the planogram based on the plurality of images, wherein the generating includes identifying and comparing objects within the plurality of images to a sales catalog include the plurality of items offered for sale by the retail establishment.

12. The system of claim 11, wherein the sales catalog includes, for at least a first item of the plurality of items offered for sale: an image of the first item, and a label identifying the first item.

13. The system of claim 8, wherein the receiving the image comprises:
receiving the image from the employee.

14. The system of claim 13, wherein the image comprises a video including the first retail location and one or more other of the one or more retail locations.

15. A non-transitory computer-readable device having instructions stored thereon that, when executed by at least one computing device, cause the at least one computing device to perform operations comprising:
receiving a planogram of a retail establishment, wherein the planogram indicates a relative location of a plurality of items offered for sale by the retail establishment placed across one or more retail locations within the retail establishment;
receiving an image of a first retail location of the one or more retail locations;
comparing the image to the portion of the planogram corresponding to the first retail location;
identifying, based on the comparing, one or more differences between the image and the portion of the planogram for the first retail location, wherein the one or more differences identify a product in the image that does not correspond to the plurality of items offered for sale in the first retail location; and
notifying an employee of the retail establishment of the one or more differences.

16. The device of claim 15, wherein the identifying comprises:
identifying, based on the planogram, a second retail location of the one or more retail locations that includes the product.

17. The device of claim 16, wherein the notifying comprises:
notifying the employee of both the first retail location where the product is located, and the second retail location to which the product should be moved by the employee.

18. The device of claim 15, wherein the receiving the planogram comprises:
receiving a plurality of images corresponding to the one or more retail locations; and
generating the planogram based on the plurality of images, wherein the generating includes identifying and comparing objects within the plurality of images to a sales catalog including the plurality of items offered for sale by the retail establishment.

19. The device of claim 18, wherein the sales catalog includes, for at least a first item of the plurality of items offered for sale: an image of the first item, and a label identifying the first item.

20. The device of claim 15, wherein the receiving the image comprises:
receiving the image from the employee.
